(19) United States
(12) Patent Application Publication
(10) Pub. No.: US 2025/0294955 A1
(43) Pub. Date: Sep. 18, 2025

(54) Photosynapse Devices and Related Photonic Integrated Circuits (PICs)

(71) Applicant: The Government of the United States of America, as represented by the Secretary of the Navy, Arlington, VA (US)

(72) Inventors: Jonathan D. Yuen, Washington, DC (US); Christopher M. Spillmann, Annandale, VA (US); Jakub Kolacz, Alexandria, VA (US); Paul A. Brown, Laurel Springs, NC (US)

(73) Assignee: The Government of the United States of America, as represented by the Secretary of the Navy, Arlington, VA (US)

(21) Appl. No.: 18/603,349

(22) Filed: Mar. 13, 2024

(51) Int. Cl. H10K 39/00; G06N 3/049; G06N 3/067; H10K 30/81; H10K 39/38

(52) U.S. Cl. CPC H10K 39/601; G06N 3/049; G06N 3/0675; H10K 30/81; H10K 39/38

(57) ABSTRACT

According to some embodiments of the present disclosure, a photosynapse device includes an insulating layer, a semiconductor layer on the insulating layer, a photoactive layer on the semiconductor layer, and a pair of spaced apart electrodes. The semiconductor layer is between the insulating layer and the photoactive layer, and the pair of spaced apart electrodes are electrically coupled with the semiconductor layer. Related photonic integrated circuit devices are also discussed.

### FEDERALLY SPONSORED RESEARCH AND DEVELOPMENT

The United States Government has ownership rights in this invention. Licensing inquiries may be directed to Office of Technology Transfer, US Naval Research Laboratory, Code 1004, Washington, D.C. 20375, USA; +1.202.767.7230; nrltechtran@us.navy.mil, referencing Navy Case #211850-US1.

### TECHNICAL FIELD

The present disclosure relates to photonic devices and related photonic integrated circuits (PICs).

### BACKGROUND

Current computers rely on von Neumann computation, where information processing happens sequentially with a central processing unit (CPU) and on-board memory. Neuromorphic computing, that is, information-processing performed by the brains and nervous systems of all complex living creatures, instead relies on concurrency of processing and memory and is an alternative way to provide computation which can potentially handle certain complex tasks better than traditional computers. Examples include multifunctional sensing, multi-object recognition and multi-signal classification.

A neuromorphic inspired system mimics central nervous system (CNS) operation, where CNS operation begins with information transmitted via the exchange of neurotransmitters between the presynaptic neuron and the postsynaptic neuron. Signal exchange between neurons is characterized by plasticity, or signal decay, where the presynaptic neuron emits a short signal pulse (known as a presynaptic spike), which generates a rapid increase (spike) followed by a gradually decaying response in the postsynaptic neuron (known as an excitatory post-synaptic response EPSR or excitatory post-synaptic current EPSC). In an artificial synapse, an optical stimulus in the form of a short light pulse may result in an excitatory postsynaptic current (EPSC), characterized by a sharp increase in current (or conductance) followed by a gradual decay.

Short term plasticity (STP) is when the signal decays back to the original state if the spike is weak or the interval between spikes is long. Long term plasticity (LTP) occurs when the spike intervals are sufficiently close such that the signal cumulatively strengthens. If the strength of the cumulative signal reaches the point where the signal decays over a long time, say hours or days, this is considered information retention. Information retention is an important component of neuromorphic learning as it enables multiple neurons to integrate the collection of retained information and use that retained information to make decisions.

Short-term potentiation (STP) is a sharp increase in current (or conductance) under a short light pulse followed by gradual current decay. Intensity of EPSC is dependent on light intensity and duration.

Paired-pulse facilitation (PPF) occurs when sequential pulses result in a second excitatory current being higher than the first excitatory current. A series of pulses results in a cumulative increase (long term potentiation or LTP).

Development of an electronic mimic was a significant challenge until the discovery of memristors in 2008 (see, Reference [1]). A memristor is a resistor that can retain a ‘memory’ of its conductive state, and a memristor has behavior analogous to that of a synapse. As discussed in Reference [2], memristive technology has provided the theoretical background and experimental methodology to easily and reliably fabricate electronic synapses. References [3] and [4] discuss examples of memristor-based electronic synapses (which rely purely on electronic current) that have been fabricated, along with neuromorphic computer chips based on such memristor-based electronic synapses. In contrast to a pure synapse, Reference [5] discusses photosynapses, or optical synapses, and References [6] and [7] discuss more recent innovations that have sparked interest as they mimic the optical nerve. A photosynapse instead relies on photons as the presynaptic spike to create an EPSR detected by a change in the photosynapse current or conductance. Image acquisition and in-sensor preprocessing may be conducted in a single readout operation, allowing the potential of direct neuromorphic computation and analysis of visual images without an intervening camera or prior image processing.

The general operation of a photosynapse is discussed as follows. Illumination of the synapse with a photonic spike generates a bound electron-hole pair (exciton), which quickly dissociates into charge carriers, with one particle bound and the other mobile. The mobile charge contributes to the immediate increase in conductance of the photosynapse followed by a gradual decrease in conductance (EPSR) after the spike as bimolecular recombination reduces the mobile carriers. Since the concentration of mobile charges generated is typically low, very thin conducting or semiconducting materials may have to be used, such as ultra-thin or 2D semiconductor layers.

Ultra-thin semiconductors include: organic materials (see Reference [8]), such as pentacene, copper-phthalocyanine (CuPc) and polymers and co-polymers of polythiophene; and inorganic materials such as zinc oxide, indium-gallium zinc oxide, and molybdenum oxide (see Reference [9]). Examples of 2D semiconductors include graphene and transition-metal chalcogenides (see Reference [10]). The separation of the exciton can occur either through a large applied electric field or through the use of a heterostructure where the exciton is generated in one material and either the electron or hole transfers into the other material due to an internal electric field created by the difference in band energies of the two materials.

One challenge is that exciton recombination in both bulk and heterostructure systems may occur in millisecond time scales and, may thus be inadequate for the seconds-timescale of most synapses.

### SUMMARY

This summary is intended to introduce in simplified form, a selection of concepts that are further described in the Detailed Description. This summary is not intended to identify key or essential features of the claimed subject matter, nor is it intended to be used as an aid in determining the scope of the claimed subject matter. Instead, it is merely presented as a brief overview of the subject matter described and claimed herein.

According to some embodiments of inventive concepts, a photosynapse device includes an insulating layer, a semiconductor layer on the insulating layer, a photoactive layer on the semiconductor layer, and a pair of spaced apart electrodes. The semiconductor layer is between the insulating layer and the photoactive layer, and the pair of spaced apart electrodes are electrically coupled with the semiconductor layer.

According to some other embodiments of inventive concepts, a photonic integrated circuit (PIC) device includes a substrate and an array of photosynapse devices on the substrate. The array of photosynapse devices includes first and second photosynapse devices. The first photosynapse device includes a first insulating layer on the substrate, a first semiconductor layer on the first insulating layer, a first photoactive layer on the first semiconductor layer, and a first pair of spaced apart electrodes electrically coupled with the first semiconductor layer, with the first semiconductor layer being between the first photoactive layer and the first insulating layer. The second photosynapse device includes a second insulating layer on the substrate, a second semiconductor layer on the second insulating layer, a second photoactive layer on the second semiconductor layer, and a second pair of spaced apart electrodes electrically coupled with the second semiconductor layer, with the second semiconductor layer being between the second photoactive layer and the second insulating layer.

### BRIEF DESCRIPTION OF DRAWINGS

Examples of embodiments of inventive concepts may be more clearly understood from the following detailed description taken in conjunction with the accompanying drawings in which:

FIG. 1A is a perspective view schematically illustrating a photosynapse device with a photoactive layer present on a graphene layer according to some embodiments of inventive concepts, and FIG. 1B is a cross sectional view of the device of FIG. 1A;

FIG. 2A is a perspective view illustrating a schematic of a graphene device without a photoactive layer where point defects are generated under illumination which in turn generate traps in graphene, and FIG. 2B is a graph illustrating normalized resistances of the graphene layer of FIG. 2A as a function of time;

FIG. 3 is a graph illustrating a negative photoconductance response of the graphene device of FIG. 2A for different wavelengths;

FIG. 4 is a graph illustrating excitatory post-synaptic current (EPSC) responses of a graphene device coated with a Brilliant Yellow photoactive layer for different wavelengths according to some embodiments of inventive concepts;

FIG. 5A is a schematic diagram illustrating a photosynapse device with a photoactive layer on a graphene layer and under illumination with exciton generation in the photoactive capping layer and transfer into the graphene layer according to some embodiments of inventive concepts, and FIG. 5B is a graph illustrating normalized resistances of the device of FIG. 5A as a function of time;

FIGS. 6A and 6B are graphs illustrating an EPSC response of a photosynapse device including a graphene layer on a quartz insulating layer capped with a Congo Red photoactive layer for light intensity (FIG. 6A) and pulse frequency (FIG. 6B, 0.05 Hz and 1 Hz) according to some embodiments of inventive concepts, with the chemical structure of Congo Red on the inset;

FIGS. 7A and 7B are graphs illustrating an EPSC response of a photosynapse device including a graphene layer on an SiC insulating layer capped with a Brilliant Yellow photoactive layer for light intensity (FIG. 7A) and pulse frequency (FIG. 7B, 0.05 Hz and 1 Hz) according to some embodiments of inventive concepts, with the chemical structure of Brilliant Yellow on the inset;

FIGS. 8A and 8B are graphs illustrating an EPSC response of a photosynapse device including a graphene layer on a quartz insulating layer capped with a tera-isopropyl-perylene dye photoactive layer for light intensity (FIG. 8A) and pulse frequency (FIG. 8B, 0.05 Hz and 1 Hz) according to some embodiments of inventive concepts, with the chemical structure of perylene on the inset;

FIG. 9 is a top view of an array of photosynapse devices according to some embodiments of inventive concepts;

FIGS. 10A-10C are cross sectional views taken alone section line 10-10′ of FIG. 9 illustrating different structures of the photosynapse devices according to some embodiments of inventive concepts;

FIG. 11 is a top schematic view of a photonic integrated circuit device including an array of photosynapse devices and control circuitry (including sensing circuitry, row address circuitry, and column address circuitry) according to some embodiments of inventive concepts;

FIG. 12A is a cross sectional view illustrating a lens coupled with an array of photosynapse devices according to some embodiments of inventive concepts; and

FIG. 12B is a cross sectional view illustrating an array of light emitting diodes coupled with an array of photosynapse devices according to some embodiments of inventive concepts.

### DETAILED DESCRIPTION

Aspects and features of the present disclosure will now be described more fully with reference to the accompanying drawings. The following description shows, by way of example, combinations and configurations in which aspects, features, and embodiments of inventive concepts can be put into practice. It will be understood that the disclosed aspects, features, and/or embodiments are merely examples, and that one skilled in the art may use other aspects, features, and/or embodiments or make functional and/or structural modifications without departing from the scope of the present disclosure. Moreover, like reference numerals refer to like elements throughout, and sizes/thicknesses/dimensions of each of the elements may be exaggerated for clarity and conveniences of explanation.

The present disclosure describes a photo-activated device with an architecture that mimics the electronic behavior of a neurological synapse, i.e. a photosynapse. Neuromorphic computing, as with quantum computing, presents an alternative way to provide computation in contrast to traditional von Neumann computers, which may currently be limited by high latency, excessive energy consumption, and/or insufficient parallelism. Complex tasks such as multifunctional sensing, multi-object recognition, and/or multi-signal classification may be more accessible via neuromorphic computation. Electronic synapses have been developed as fundamental units of neuromorphic computer architectures, akin to a transistor in a central processing unit (CPU), of which photosynapses represent a subset of development. The present disclosure describes embodiments of a two-terminal photosynapse based on a planar photoresistor design, demonstrating that a two-terminal photosynapse may closely mimic the behavior of a synapse, such as an optical synapse, and that a two-terminal photosynapse may rely on only one electrically active layer for operation.

Hence, an effective trapping mechanism is disclosed. This can be done by creating trapping sites through defects and/or creating a heterostructure including an intervening insulator (i.e., a large bandgap material) or a trapping interface between the two materials. Nanoscale materials or nanomaterials, such as 2-dimensional (2D) semiconductors, nanowires and quantum-dots (QDs) may be useful materials to trap charges because defects can be generated easily in these materials. Quantum dots in particular have intrinsic intervening layers when grown as core-shell structures or when coated with insulating ligands. Examples of nanomaterials include boron nitride, carbon nanotubes, perovskite QDs, lead-based QDs and cadmium-based QDs (see, Reference [10]). Heterostructure photosynapses may include two to three layers: a conduction layer, an exciton generation layer, and a possible intervening recombination barrier layer. The exciton layer may also serve to trap charges, allowing the mobile charges to transfer into the conduction layer, thereby lowering the resistance of the device. The recombination barrier serves to delay the recombination of the separated charges in the case that the exciton layer does not contain long lifetime traps. Long lifetime traps may also be introduced at the interface of the exciton and conduction layers for two layer structures.

The materials in photosynapses may generally be difficult and/or expensive to grow, and fabrication of devices may be challenging. Small molecule semiconductors (e.g., pentacene, copper phthalocyanine CuPc, etc.) and inorganic oxide semiconductors may require high vacuum to deposit and may crystalize easily, resulting in non-uniformities, while polymer semiconductors (e.g., polythiophenes) are typically formed by spin-casting. Non-uniformities may hinder effective charge transport, contributing to low mobilities and/or high voltage operation.

For 2D materials other than graphene and boron nitride, growth of large wafer-scale single crystal 2D layers has not been achieved. QDs may be difficult to synthesize in bulk quantities, may be expensive, and/or may contain toxic materials such as lead and/or cadmium. Moreover, the need to synthesize materials for the excitation/trapping layer that not only generate excitons, but also contain specific trap sites which promote long recombination times, may create a limitation to the type of materials that can be used. In terms of device structure, current architectures may also be problematic. Typically, most two-terminal photosynapses are vertical sandwich type devices, which may be difficult to fabricate due to the challenge of coating each layer on top of one other layer and then etching the layers completely to form separate devices.

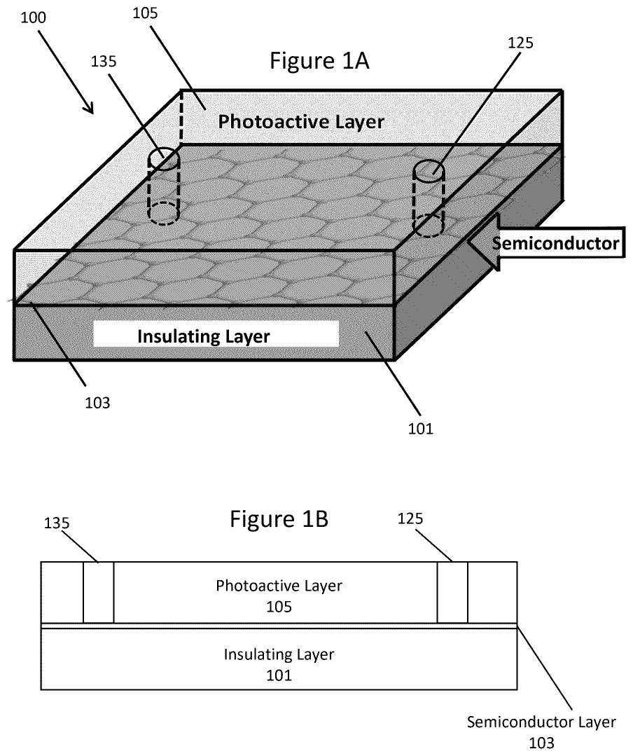

In some embodiments of the present disclosure, a photosynapse device includes a planar structure which may be fabricated without need for specialized equipment. While work has been done on device fabrication, not much work has been done to clearly distinguish the roles of individual layers. For example, nanomaterials may be capable of charge transport and may contribute to the photoconductance of the device. Additionally, the role of trap sites in the 2D or semiconducting layers also have not been elucidated. In some embodiments of the present disclosure shown in FIGS. 1A and 1B, a photosynapse device 100 includes graphene layer 103 sandwiched between insulating layer 101 (e.g., a silicon-based insulating layer) and photoactive layer 105 (e.g., an organic photoactive capping layer), also referred to as a photoactive capping layer. Photosynapse device 100 may also include spaced apart electrodes 125 and 135 that are electrically coupled with graphene layer 103. As shown, electrodes 125 and 135 may extend through photoactive layer 105.

Device 100 is shown schematically in FIGS. 1A and 1B. Organic photoactive layer 105 (also referred to as a photolayer) is shown at the top of FIGS. 1A and 1B, where excitons are generated upon exposure to a photonic stimulus (e.g., light or illumination). Below organic photoactive layer 105, graphene layer 103 acts as a conductive layer in which the photosynaptic behavior is probed, and graphene layer 103 provides trapping sites for the excitons generated by organic photoactive layer 105. This is distinct from devices mentioned previously where trap sites are located in the photolayer itself. The device structure of FIGS. 1A and 1B differs mechanistically from other memristor devices, for example, in that the trapping layer is separate from the exciton generation layer.

The photosynapse device 100 of FIGS. 1A and 1B may be fabricated according to some embodiments of inventive concepts using the following operations. First, a layer of graphene 103 is either grown directly on insulating layer 101 (e.g., epitaxial growth on silicon carbide SiC), or a layer of graphene 103 is transferred to insulating layer 101 using established techniques. A thin film of organic photoactive layer 105 is then spin-cast on graphene 103, for example, using spin-casting (also referred to as spin-coating). Since organic photoactive layer 105 is not used for conduction, in contrast to devices noted previously, non-uniformity of photoactive layer 105 may not significantly affect overall performance of the device. In some embodiments of inventive concepts, organic photoactive layer 105 may completely cover graphene layer 103 to increase/maximize exciton generation and charge transfer. Finally, contacts may be added to graphene layer 103 to characterize the device.

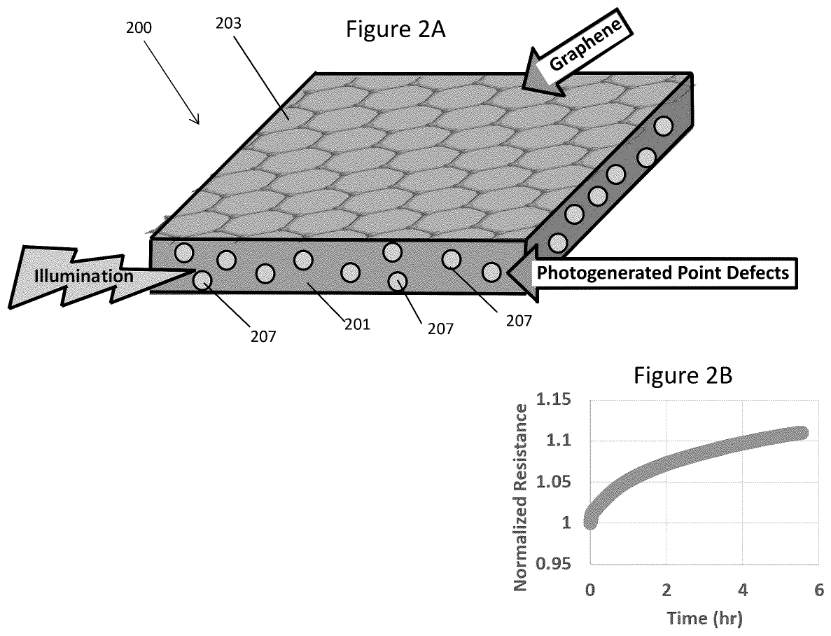

Behavior of a device 200 including graphene layer 203 on silicon-based insulating layer 201 (such as silicon carbide SiC, silicon nitride SiN, or silicon dioxide SiO₂) without a photoactive layer (as shown in FIG. 2A) is first described to distinguish the properties of each layer. As opposed to devices described previously where a concentration of engineered trap sites may remain fixed, photogeneration of defects in insulating layer 201 (and/or on the surface thereof) may cause charge trapping sites in graphene layer 203 in FIG. 2A, resulting in reduced conductivity under illumination. Stated in other words, graphene layer 203 may exhibit increasing resistance (photoresistance) when exposed to light. Charged point defects 207 are generated under photo illumination both in the bulk and the surface of insulating layer 101, thus causing trap states to form in graphene layer 203. These trap states capture mobile charges in graphene layer 203, causing a loss in conductivity (referred to as photoresistance or negative photoconductance). Graphene layer 203 therefore acts as a photoresistor in the presence of illumination. This is mechanistically illustrated in FIG. 2A.

FIG. 2B is a graph illustrating the gradually increasing photoresistance of graphene layer 203 as a function of time when illuminated. The explanation for this phenomenon is the photogeneration of defects in insulating layer 201 and on the surface of insulating layer 201 which in turn creates charge trapping sites in graphene layer 203.

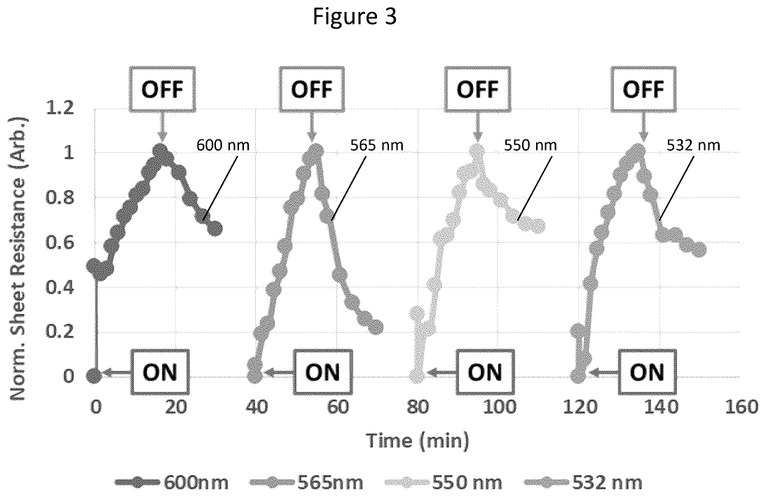

FIG. 3 is a graph illustrating resistivity of device 200 of FIG. 2A (i.e., without an organic photoactive capping layer) as it is exposed to illumination at four different wavelengths of light (600 nm, 565 nm, 550 nm and 532 nm). At all wavelengths, there is a continuous logarithmic increase in resistance as the device is exposed to light, indicating the generation of traps in graphene layer 203. When the light is removed (indicated as “OFF”), an abrupt transition occurs where the defects 207 in insulating layer 201 start to become passivated and reduce in quantity, decreasing the number of trap states in graphene layer 203 and, therefore, reducing resistance through graphene layer 203.

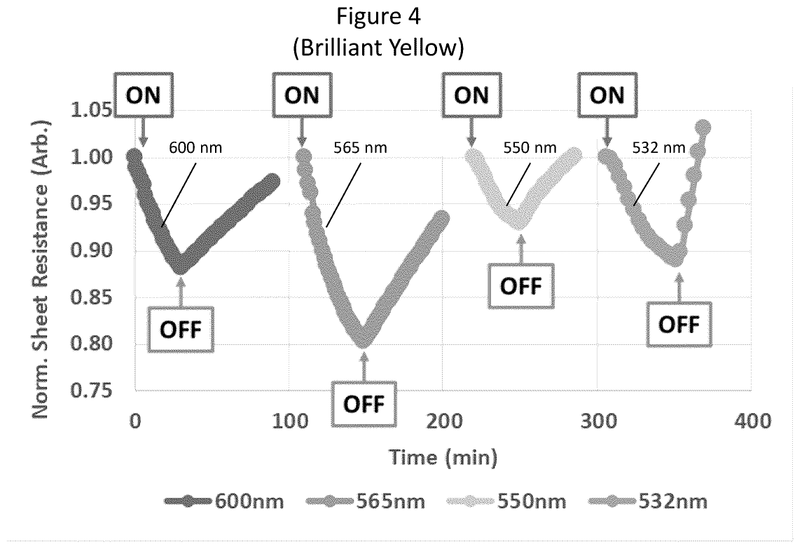

When photoactive layer 105 is introduced onto graphene layer 103 (as shown in FIGS. 1A and 1B) and the device is exposed to illumination, an opposite response in the form of positive photoconductance/EPSR is instead observed as shown in FIG. 4 with Brilliant Yellow provided as photoactive layer 105. The photogenerated trap states in graphene layer 103 (that result from illuminating insulating layer 101) are simultaneously filled by photoexcited charges originating from organic photoactive layer 105, along with the generation of untrapped mobile charges. Other dyes such as HAT5 may also be used to provide photoactive layer 105.

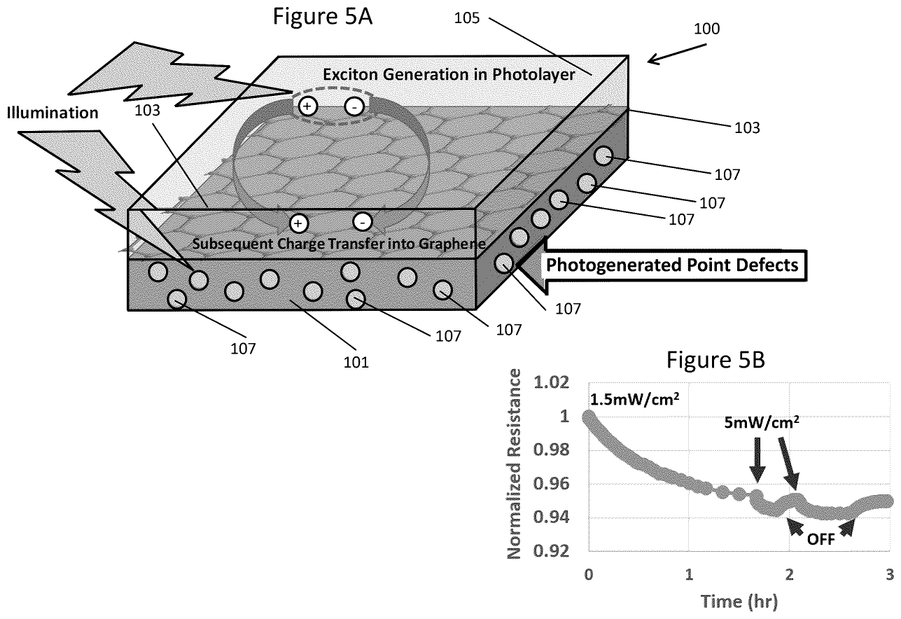

FIG. 5A shows a schematic of the device of FIGS. 1A and 1B with photoactive layer 105 under illumination, in which excited charges (excitons) generated in photoactive layer 105 are transferred into graphene layer 103. Some of the charges are subsequently trapped in graphene layer 103 by the photogenerated trap states described above with respect to FIGS. 2A, 2B, and 3, while other charges remain mobile and contribute to increased conductance (reduced resistance) of graphene layer 103, which now acts as a photoconductor. FIG. 5B is a graph illustrating a gradual reduction in resistance as illumination is applied to device 100. Charge separation of excitons formed in photoactive layer 105, followed by charge transfer, results in the photodoping of graphene layer 103, resulting in steadily lowering resistance (or increasing photoconductivity) of graphene layer 103. Stated in other words, when photoactive layer 105 is provided on graphene layer 103, graphene layer exhibits decreasing resistance (photoconductance) when exposed to light.

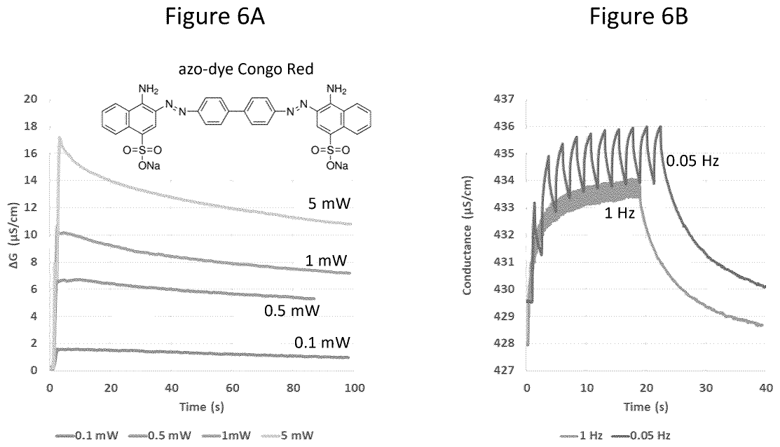

Further evidence of EPSR is shown in the data provided in the graph of FIGS. 6A and 6B which was collected from device 100 including graphene layer 103 on quartz (SiO₂) insulating layer 101 and capped with photoactive layer 105 of azo-dye Congo Red (having the chemical structure shown above the graph of FIG. 6A). Under illumination of a 0.5 second light pulse with the different indicated intensities (0.1 mW, 0.5 mW, 1 mW, and 5 mW), EPSR/EPSC and increasing conductance is observed with time scales in the minutes to show the effect of photon intensity on EPSR/EPSC. Likewise, relaxation time upon removal of the photo stimulus is observed over minutes. In the graph of FIG. 6A, short term plasticity (STP) in the change in conductance is observed if the intensity of illumination is low enough. In the instance of this device, a single 0.5 second light pulse at 0.1 mWcm⁻² results in a return to the original state in ˜2 minutes. Long term plasticity (LTP) is observed under illumination at high intensities.

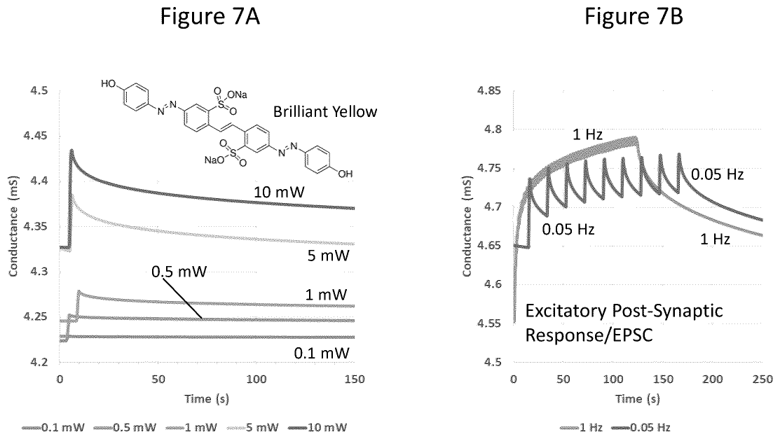

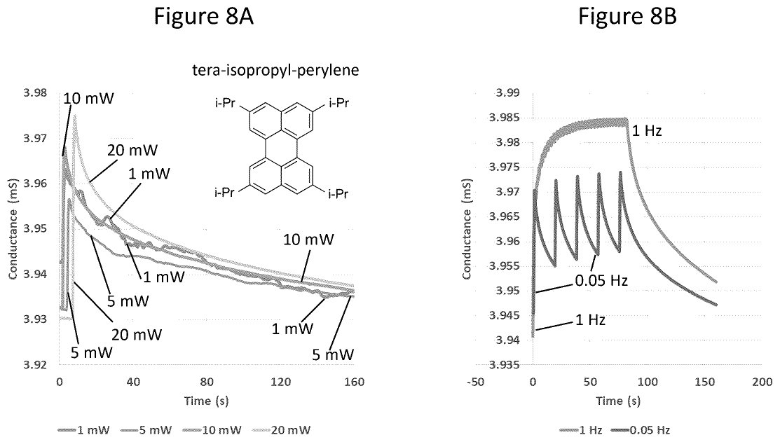

LTP, in the form of cumulatively increasing conductance, is also observed in FIG. 6B when 0.5 second light pulses at 1 mWcm⁻² were applied at 0.05 Hz and at 1 Hz. The observation of STP and LTP in the photoconductance of the device 100 is a direct observation of photosynaptic behavior. The photosynaptic response with photoactive layers 105 of other photoactive materials deposited as thin films (i.e., Brilliant Yellow, Methyl Orange, tetra-isopropyl-perylene) and with graphene layer 103 on different insulating layers (SiC) were repeated, as shown in FIGS. 7A-7B and FIGS. 8A-8B.

The data of FIGS. 7A and 7B was obtained using device 100 of FIGS. 1A and 1B with a Brilliant Yellow die as photoactive layer 105, graphene as layer 103, and silicon carbide (SiC) as insulating layer 101. FIG. 7A shows the EPSC response of the device under a 0.5 second light pulse with different intensities (0.1 mW, 0.5 mW, 1 mW, 5 mW, and 10 mW), showing the effect of photon intensity on EPSC response. FIG. 7B shows the EPSC response of the device under a 0.5 second light pulse at 1 mWcm⁻² at different pulse frequencies (1 Hz and 0.05 Hz), showing the cumulative effect of long term potentiation.

The data of FIGS. 6A-B, 7A-B, and 8A-B was obtained using Hall Effect measurements under a light source, and the doping effects could last over hours and/or days.

Various aspects of device 100 of some embodiments disclosed herein are discussed below. According to some embodiments, graphene layer 103 acts as both a transport layer and also as a charge trapping layer, and/or traps are dynamically generated during illumination. Previous devices in general may rely on a fixed quantity of traps intrinsic to the materials in the device.

Another difference of some embodiments is the distinction between photoactive layer 105 which acts to provide photogeneration and graphene layer 103 which acts as a transport layer. As mentioned previously, materials described in previous photosynaptic devices are capable of both photoexcitation and charge transport, and there is no clear delineation of operation associated with the materials used. With devices of some embodiments disclosed herein, graphene layer 103 does not generate significant mobile charges under illumination as its resistance increases with photoexposure. Additionally, the dyes used for photoactive layer 105 may be electrically insulating and may not transport significant charge according to some embodiments, so that they act as an exciton source without providing significant charge transport.

Hence, the roles that the materials play in operation of device 100 may be differentiated according to some embodiments, and device 100 may have a single photoexcitation layer (provided by photoactive layer 105) and a single transport layer (provided by graphene layer 103) according to some embodiments. Finally, based on a large material space demonstrated, device architectures of FIGS. 1A-B may be very general and other material combinations may be used to provide similar photosynaptic behavior.

According to some embodiments of inventive concepts, device 100 includes three layers: insulating layer 101, graphene layer 103, and photoactive layer 105. When illuminated with light, insulating layer 101 forms photogenerated defects, photoactive layer 105 forms excitons, and graphene layer provides charge transport. The photogenerated defects in insulating layer 101 create trap sites in graphene layer 103 and these trap sites in turn are doped by the transfer of photogenerated excited charges (excitons) from photoactive layer 105, resulting in a long term increase in conductance in graphene layer 103. The observed effect of increased conductivity of graphene layer 103 can be used to develop an artificial synapse in which photodoping effects can be used to create an excitatory postsynaptic current, which then can be used to induce synaptic behaviors such as short term potentiation, paired pulse facilitation, and/or long term potentiation.

Electronic devices form the computational backbone of many military and commercial systems, including weapons, sensors, and medical devices. With Moore's law potentially approaching limits, neuromophic computing may present an alternative computational methodology that may address this issue. Potential applications for this phenomenon are numerous, including photomemory, neuromorphic computing, memtransistors, and applications for logic and integrated circuits. Such devices may also be used as time-exposure sensors for optically sensitive materials.

Some embodiments of inventive concepts may be provided using material sets that are less complicated than those previously used. Photoactive layer 105, for example, may only require a material that generates excitons, and many commonly available materials, such as azo-dyes, can be used. Moreover, some embodiments of inventive concepts may be fabricated without specialty nanoscale materials such as QDs. Many of the materials used for current photosynapses may be highly dependent on nanoscale and mesoscale materials, which may be challenging to synthesize, to integrate into devices, and/or to keep stable under operation conditions.

Some embodiments of inventive concepts may provide simpler device architectures. Photosynapse device 100 of FIGS. 1A and 1B may be provided as a planar structure, which may be easier to fabricate with reduced/no need for highly specialized equipment. Device 100 may be fabricated using 3 layers, including insulating layer 101, and may be easily translatable into many different applications from applications including CMOS technology to applications such as flexible electronics.

Some embodiments of inventive concepts may be highly translatable. Methodologies of inventive concepts disclosed herein may be very general such that the technology may extend to large sets of photosensitive materials and 2D materials. Any material that can create excitons can be used as photoactive layer 105. Alternative 2D materials such as chalcogenides and/or group IV materials can be used in place of graphene layer 103. Very thin semiconductor materials such as oxides and/or standard semiconductors can be used.

Photosynapse device 100 may thus provide an artificial synapse including a graphene layer 103 (or other 2D layer) sandwiched between photoactive layer 105 and silicon containing insulating layer 101, and the electronic learning behavior is provided by the cumulative increase of photoconductance measured across graphene layer 103 in response to illumination. Uses for such devices may include photomemory, neuromorphic computing, memtransistors, and/or applications for logic and/or integrated circuits. Moreover, photosynapse device 100 may be used as a time exposure sensor for optically sensitive materials.

With photoactive layer 105 thereon, graphene layer 103 exhibits increasing photoconductance (or decreasing photoresistance) when exposed to light. Moreover, timescales of gain and relaxation may be on the order of hours and days (thus providing photodoping and photomemory). Accordingly, the timescales of gain and relaxation may be long enough that this behavior can be implemented to provide an artificial synapse.

Embodiments of inventive concepts may thus provide an artificial synapse using an electrically insulating organic-dye as photoactive layer 105 to provide an electron source, and the organic-dye photoactive layer 105 may be applied using spin-on and/or printing techniques. Moreover, such organic-dye photoactive layers may provide long term use/stability (e.g., over six months), with limited/no photobleaching and/or degradation. Moreover, such organic-dye photoactive layers may be compatible with cleanroom fabrication techniques. These electrically insulating organic-dye photoactive layers may provide automatic charge trapping and delayed photoconductance. Moreover, photosynapse device 100 may be provided as a two terminal device because photoconductance is intrinsic to the device.

The three layer structure of FIGS. 1A-B may be provided using low-cost and commercially available photoactive materials for photoactive layer 105, thereby reducing/avoiding use of more expensive/exotic materials such as photoactive nanomaterials. Moreover, the three layer structure may be relatively easy and/or inexpensive to manufacture.

A variety of materials can be used as insulating layer 101 such that insulating layer 101 supports integrity of the 2D material and such that it can induce the formation of trap states in the 2D material.

Any 2D electronic materials can be considered for use in place of graphene layer 103. Examples include, but are not limited to, metal oxides, borides, chalcogenides, pnictides, perovskites, nitrides, doped or charged semiconductors (such as silicon and phosphorous), and metalloids (such as boron, germanium, antimony, and bismuth).

Any photosensitive material can be considered for use as photoactive layer 105. Examples include, but are not limited to, intrinsic polymers, modified polymers, mesoporous and microporous organic and inorganic systems, metal-organic frameworks (MOFs), zeolites, biomaterials, and hydrogels.

The electrodes 125 and 135 (also referred to as contacts) may be provided using one or more metals, alloys, and/or conductive materials; such as gold, aluminum, nickel, silver, poly(3,4-ethylenedioxythiophene) polystyrene sulfonate PEDOT:PSS, and chromium.

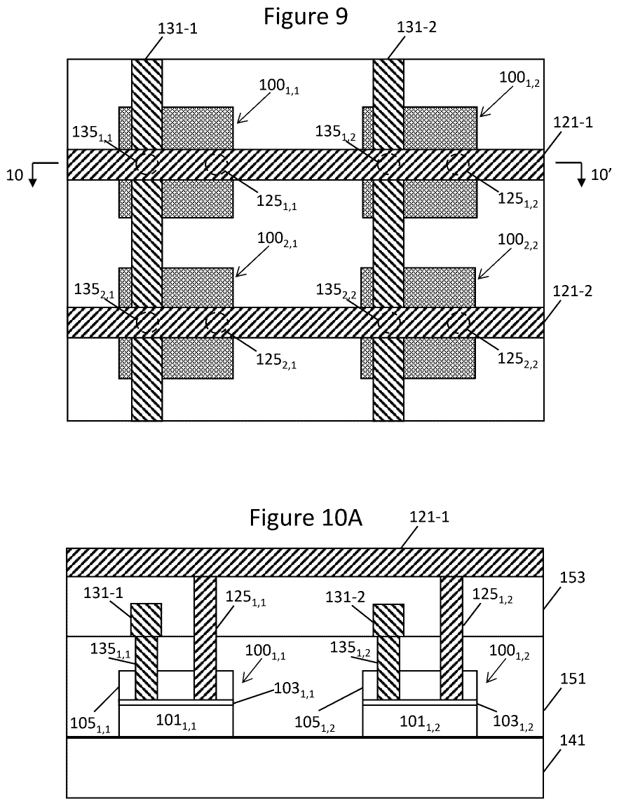

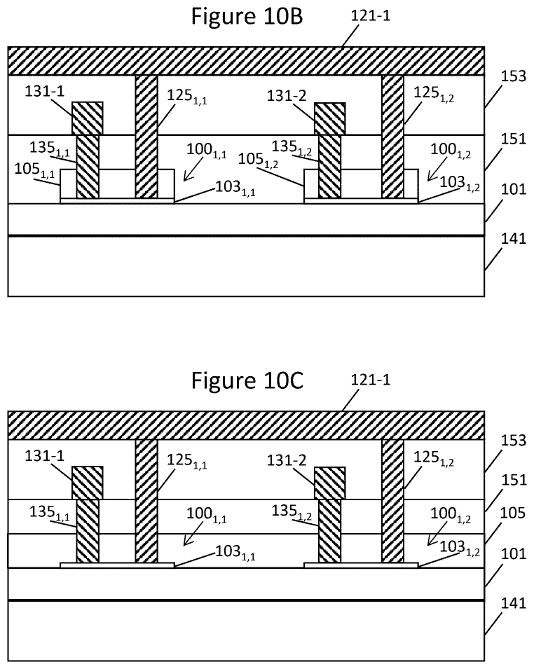

In some embodiments, contacts/electrodes may be coupled with another substrate/device using solder/wire bonds. Alternative methods to attach electrodes/contacts can be used, such as replacing solder with conductive epoxy, ball bonding, and/or adhesives. In a PIC, electrodes/contacts may be coupled with conductive row/column lines as discussed below with respect to FIGS. 9, 10A-C, and 11.

Alternative methods to deposit the photoactive layer 105 can be used, such as inkjet printing, screen-printing, lithography, gravure, roll-to-roll, spray-printing, batik, laser, flexography, thermal-printing, stamping, intaglio, lamination, adhesion, evaporation, sputtering, and/or ablation.

Illumination of device 100 may take place directly using a coherent or incoherent light source. The light can cover any portion of the absorbance spectrum of the device.

Various embodiments are discussed below with reference to the drawings.

According to some embodiments illustrated in FIGS. 1A and 1B, photosynapse device 100 includes insulating layer 101, semiconductor layer 103 on insulating layer 101, photoactive layer 105 on semiconductor layer 103, and spaced apart electrodes 125 and 135 electrically coupled with semiconductor layer 103. As shown, electrodes 125 and 135 may extend through photoactive layer 105. According to some other embodiments, photoactive layer 105 may be provided on central portions of semiconductor layer 103 with opposing edges of semiconductor layer 103 remaining free of photoactive layer 105, and electrodes 125 and 135 may be electrically coupled with the opposing edges of semiconductor layer 103 without extending through photoactive layer 105. According to still other embodiments, electrodes 125 and 135 may contact a bottom surface of semiconductor layer 103, for example, extending through insulating layer 101 or contacting portions of semiconductor layer 103 that extend beyond insulating layer 101 (such that insulating layer 101 is between the electrodes).

Semiconductor layer 103 may have an atomic scale thickness, semiconductor layer 103 may have a thickness less than about 5 nanometers, and/or semiconductor layer 103 may be a 2-dimensional electronic semiconductor layer. Semiconductor layer 103 may include at least one of graphene, a chalcogenide, a group IV semiconductor material, a metal oxide, a metal boride, a pnictide material, a perovskite material, a nitride material, silicon, phosphorous, a metalloid, boron, germanium, antimony, and/or bismuth.

Insulating layer 101 may include a silicon-based insulating layer, for example, including one or more of silicon carbide, quartz, silicon dioxide, and/or silicon nitride. Photoactive layer 105 may include an organic photoactive layer, for example, including one or more of an organic photoactive dye, and/or an azo-dye. More particularly, organic photoactive layer 105 may include at least one of Congo red, azo-dye Congo Red, Brilliant yellow, Methyl Orange, perylene, tera-isopropyl-perylene, HAT5, an intrinsic polymer, a modified polymer, a mesoporous system, a microporous system, a metal-organic framework (MOF), a zeolite, a biomaterial, and/or a hydrogel.

Each of electrodes 125 and 135 may include at least one of gold, aluminum, nickel, silver, poly(3,4-ethylenedioxythiophene) polystyrene sulfonate PEDOT PSS, and/or chromium.

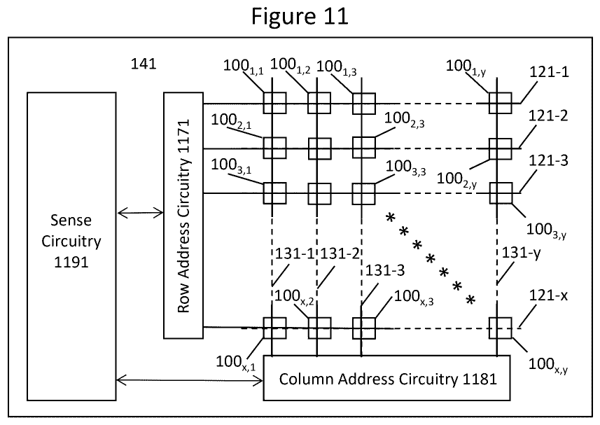

According to some embodiments of FIGS. 9, 10A, 11, 12A, and/or 12B, photosynapse device 100_{1,1} includes insulating layer 101_{1,1}, semiconductor layer 103_{1,1} on insulating layer, 101_{1,1}, photoactive layer 105_{1,1} on semiconductor layer 103_{1,1}, and spaced apart electrodes 125_{1,1} and 135_{1,1} electrically coupled with semiconductor layer 103_{1,1}. Insulating layer 101_{1,1} of FIG. 10A may be provided as discussed above with respect to insulating layer 101 of FIG. 1A; semiconductor layer 103_{1,1} of FIG. 10A may be provided as discussed above with respect to semiconductor layer 103 of FIG. 1A; photoactive layer 105_{1,1} of FIG. 10A may be provided as discussed above with respect to photoactive layer 105 of FIG. 1A; and electrodes 125_{1,1} and 135_{1,1} of FIG. 10A may be provided as discussed above with respect to electrodes 125 and 135 of FIG. 1A. The same and/or similar structures may be applied with respect to photosynapse devices 100_{1,2}, 100_{2,1}, and/or 100_{2,2}, or with respect to any of photosynapse devices 100_{1,1} to 100_{x,y} of FIG. 11.

According to some embodiments of FIGS. 9, 10B, 11, 12A, and/or 12B, photosynapse device 100_{1,1} includes insulating layer 101, semiconductor layer 103_{1,1} on insulating layer 101, photoactive layer 105_{1,1} on semiconductor layer 103_{1,1}, and spaced apart electrodes 125_{1,1} and 135_{1,1} electrically coupled with semiconductor layer 103_{1,1}. Insulating layer 101 of FIG. 10B may be provided as discussed above with respect to insulating layer 101 of FIG. 1A; semiconductor layer 103_{1,1} of FIG. 10B may be provided as discussed above with respect to semiconductor layer 103 of FIG. 1A; photoactive layer 105_{1,1} of FIG. 10B may be provided as discussed above with respective to photoactive layer 105 of FIG. 1A; and electrodes 125_{1,1} and 135_{1,1} of FIG. 10B may be provided as discussed above with respect to electrodes 125 and 135 of FIG. 1A. The same and/or similar structures may be applied with respect to photosynapse devices 100_{1,2}, 100_{2,1}, and/or 100_{2,2}, or with respect to any of photosynapse devices 100_{1,1} to 100_{x,y} of FIG. 11.

According to some embodiments of FIGS. 9, 10C, 11, 12A, and/or 12B, photosynapse device 100_{1,1} includes insulating layer 101, semiconductor layer 103_{1,1} on insulating layer 101, photoactive layer 105 on semiconductor layer 103_{1,1}, and spaced apart electrodes 125_{1,1} and 135_{1,1} electrically coupled with semiconductor layer 103_{1,1}. Insulating layer 101 of FIG. 10C may be provided as discussed above with respect to insulating layer 101 of FIG. 1A; semiconductor layer 103_{1,1} of FIG. 10C may be provided as discussed above with respect to semiconductor layer 103 of FIG. 1A; photoactive layer 105 of FIG. 10C may be provided as discussed above with respective to photoactive layer 105 of FIG. 1A; and electrodes 125_{1,1} and 135_{1,1} of FIG. 10C may be provided as discussed above with respect to electrodes 125 and 135 of FIG. 1A. The same and/or similar structures may be applied with respect to photosynapse devices 100_{1,2}, 100_{2,1}, and/or 100_{2,2}, or with respect to any of photosynapse devices 100_{1,1} to 100_{x,y} of FIG. 11.

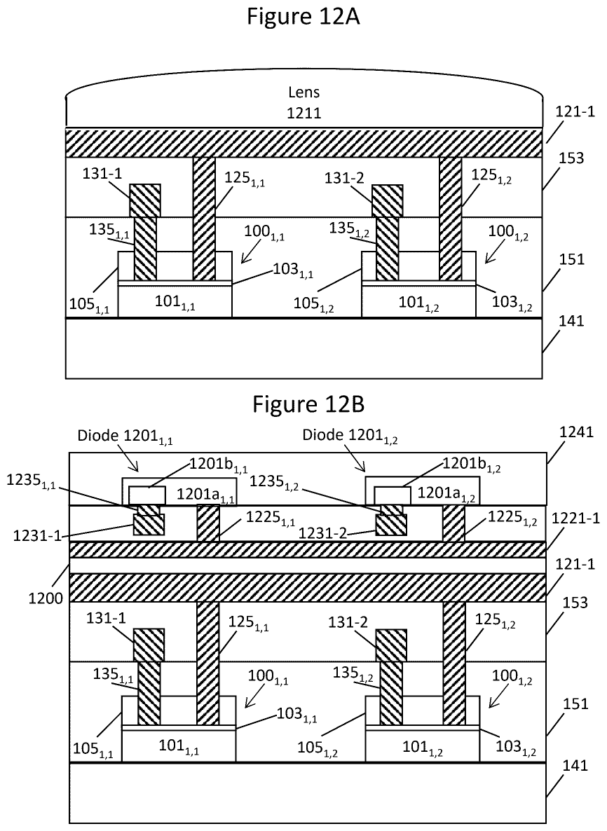

According to some embodiments shown in FIG. 12A, photosynapse devices of FIGS. 9, 10A-C, and/or 11 may be provided with lens 1211 that is optically coupled with the respective photoactive layer 105_{1,1}. According to some other embodiments shown in FIG. 12B, photosynapse devices of FIGS. 9, 10A-C, and/or 11 may be provided with light emitting diode 1201_{1,1} that is optically coupled with photoactive layer 105_{1,1}, and light emitting diode 1201_{1,1} may be configured to generate a photonic stimulus that is directed to photoactive layer 105_{1,1}.

According to some embodiments shown in FIGS. 9, 10A-C, and 11, a photonic integrated circuit (PIC) may include an array of photosynapse devices 100_{1,1} to 100_{x,y} arranged in x rows and y columns on substrate 141. FIG. 9 is a top view illustrating four photosynapse devices 100_{1,1}, 100_{1,2}, 100_{2,1}, and 100_{2,2} of such an array, and FIG. 11 is a schematic top view illustrating an array of photosynapse devices including any number x of rows and any number y of columns. FIGS. 10A, 10B, and 10C are cross sectional views illustrating different structures of photosynapse devices 100_{1,1} and 100_{1,2} in such an array according to some embodiments (e.g., as discussed above).

In each of FIGS. 10A-C, first photosynapse device 100_{1,1} includes: first insulating layer 101_{1,1} or 101 on substrate 141; first semiconductor layer 103_{1,1} on the first insulating layer; first photoactive layer 105_{1,1} or 105 on the first semiconductor layer; and a first pair of spaced apart electrodes 125_{1,1} and 135_{1,1} electrically coupled with first semiconductor layer 103_{1,1}. Similarly, second photosynapse device 100_{1,2} includes: second insulating layer 101_{1,2} or 101 on substrate 141; second semiconductor layer 103_{1,2} on the second insulating layer; second photoactive layer 105_{1,2} or 105 on the second semiconductor layer; and a second pair of spaced apart electrodes 125_{1,2} and 135_{1,2} electrically coupled with second semiconductor layer 103_{1,2}. Such structures may be applied to any of photosynapse devices 100_{1,1} to 100_{x,y} of FIG. 11.

As further shown in FIGS. 9, 10A-C, and 11, conductive row lines 121-1, 121-2, . . . 121-x may extend in a first direction, with each conductive row line being electrically coupled with respective first electrodes of the photosynapse devices in the respective row. Similarly, conductive column lines 131-1, 131-2, . . . 131-y may extend in a second direction with each conductive column lines being electrically coupled with respective second electrodes of the photosynapse devices in the respective column. The first and second directions are different. For example, the first and second directions may be orthogonal.

As shown in the top schematic view of FIG. 11, photonic integrated circuit (PIC) device 141 may include an array of photosynapse devices 100_{1,1} to 100_{x,y} and control circuitry (including sensing circuitry 1191, row address circuitry 1171, and column address circuitry 1181) according to some embodiments of inventive concepts. In such embodiments, PIC device 141 may include any number (“x”) of rows of photosynapse devices (where a conductive row line 121 is provided for each row of photosynapse devices), and any number (“y”) of columns of photosynapse devices (where a conductive column line 131 is provided for each column of photosynapse devices). Moreover, sense circuitry 1191 may be coupled with conductive row lines 121-1 to 121-x through row address circuitry 1171, and sense circuitry 11191 may be coupled with conductive column lines 131-1 to 131-y through column address circuitry 1181. Accordingly, sense circuitry 1191 can be used to sense/measure conductivities/resistivities of photosynapse devices individually or in groups.

As shown in FIG. 12A, the PIC may include lens 1211 that is optically coupled with the array of photosynapse devices, with lens 1211 being oriented to direct photonic stimulus to the photoactive layer/layers of the array of photosynapse devices. In such embodiments, a single lens 1211 may direct photonic stimulus to the photoactive layer/layers of all of the photosynapse devices of the array shown in FIG. 11. According to some other embodiments, lens 1211 may include an array of lenses with each lens of the array of lenses directing photonic stimulus to one or a group of photosynapse devices of the array of photosynapse devices.

As shown in FIG. 12B, the PIC may include an array of light emitting diodes (LEDs) on the array of photosynapse devices, with each light emitting diode of the array being optically coupled with a respective photosynapse device of the array. In such embodiments, the array of LEDs may include a number of LEDs equal to the number of photosynapse devices of the array of photosynapse devices such that each photosynapse device of the array is optically coupled with a respective LED. Accordingly, each LED may be configured to generate a photonic stimulus that is directed to a photoactive layer of a respective photosynapse device. According to some other embodiments, each LED may be configured to generate a photonic stimulus that is directed to photoactive layers of a respective group of photosynapse devices of the array.

As shown in FIG. 10A, the first and second insulating layers 101_{1,1} and 101_{1,2} may be respective first and second spaced apart islands of the insulating material, the first and second semiconductor layers 103_{1,1} and 103_{1,2} may be respective first and second spaced apart islands of the semiconductor material, and the first and second photoactive layers 105_{1,1} and 105_{1,3} may be respective first and second spaced apart islands of the photoactive material.

As shown in FIGS. 10B and 10C, the first and second insulating layers may be respective first and second portions of a continuous layer 101 of an insulating material, and the first and second semiconductor layers 103_{1,1} and 103_{1,2} may be respective first and second spaced apart islands of the semiconductor material. In such embodiments, the continuous layer 101 of the insulating material may be provided by a portion of substrate 141, or the continuous layer 101 may be provided as a separate layer of the insulating material on substrate 141.

As shown in FIG. 10C, the first and second semiconductor layers 103_{1,1} and 103_{1,2} may be respective first and second spaced apart islands of the semiconductor material, and the first and second photoactive layers may be respective first and second portions of a continuous layer of a photoactive material 105. In embodiments with a continuous layer of the photoactive material 105, insulating layers may be provided as a continuous layer 101 as shown in FIG. 10C, or as separate islands of insulating material as discussed above with respect to FIG. 10A.

Each of semiconductor layers 103_{x,y} may be provided as discussed above with respect to semiconductor layer 103 of FIG. 1A. Each of insulating layers 101_{x,y} (or insulating layer 101) may be provided as discussed above with respect to insulating layer 101 of FIG. 1A. Each of photoactive layers 105_{x,y} (or photoactive layer 105) may be provided as discussed above with respect to photoactive layer 105 of FIG. 1A. Moreover, each of electrodes 125_{x,y} and 135_{x,y} may be provided as discussed above with respect to electrodes 125 and 135.

The terminology used herein is for the purpose of describing particular embodiments only and is not intended to be limiting of inventive concepts. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof. The term “and/or” includes any and all combinations of one or more of the associated listed items.

Spatially relative terms, such as “beneath,” “below,” “lower,” “above,” “upper,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

It will be understood that, although the terms first, second, third, etc. may be used herein to describe various elements, these elements should not be limited by these terms. These terms are only used to distinguish one element from another element. Thus, a first element discussed herein could be termed a second element without departing from the scope of the present inventive concepts.

It will also be understood that when an element is referred to as being “on,” “connected” to/with, or “coupled” to/with another element, it can be directly on, directly connected to/with, or directly coupled to/with the other element, or intervening elements may be present. In contrast, when an element is referred to as being “directly on”, “directly connected” to/with, or “directly coupled” to/with another element, there are no intervening elements present. Moreover, if an element is referred to as being “on” another element, no spatial orientation is implied such that the element can be over the other element, under the other element, on a side of the other element, etc.

Embodiments are described herein with reference to cross-sectional and/or perspective illustrations that are schematic illustrations of idealized embodiments (and intermediate structures). As such, variations from the shapes of the illustrations as a result, for example, of manufacturing techniques and/or tolerances, are to be expected. Thus, embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present inventive concepts.

The operations of any methods disclosed herein do not have to be performed in the exact order disclosed, unless an operation is explicitly described as following or preceding another operation and/or where it is implicit that an operation must follow or precede another operation. Any feature of any of the embodiments disclosed herein may be applied to any other embodiment, wherever appropriate. Likewise, any advantage of any of the embodiments may apply to any other embodiments, and vice versa. Other objectives, features and advantages of the enclosed embodiments will be apparent from the description herein.

Unless otherwise defined, all terms (including technical and scientific terms) used herein have the same meaning as commonly understood by one of ordinary skill in the art to which the inventive concepts herein belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

While inventive concepts have been particularly shown and described with reference to examples of embodiments thereof, it will be understood that various changes in form and details may be made therein without departing from the spirit of the following claims.

Citations are provided below for the references cited herein. The disclosures of each of these references are hereby incorporated herein in their entireties by reference.

Reference [1]. D. B. Strukov, et al., “The missing memristor found,” Nature, Vol. 453(7191), pages 80-83, May 1, 2008.

Reference [2]. S. H. Jo, et al., “Nanoscale memristor device as synapse in neuromorphic systems,” Nano Lett., Vol. 10(4), pages 1297-1301 March 1, 2010.

Reference [3]. M. P. Sah, et al. “Brains are made of memristors,” IEEE Circuits and Systems Magazine, 1^{st} Quarter, 2014, pages 12-36.

Reference [4]. M. A. Zidan, et al., “The future of electronics based on memristive systems,” Nature Electronics, Vol. 1, pages 22-29, January 2018.

Reference [5]. J. Zhu, et al., (2020) “A comprehensive review on emerging artificial neuromorphic devices,” Appl. Phys. Rev., Vol. 7, 011312, pages 1-107 (2020).

Reference [6]. Y. Wang, et al., “Optoelectronic synaptic devices for neuromorphic computing,” Adv. Intell. Syst., Vol. 3, 2000099, pages 1-21, (2021).

Reference [7]. M. S. Kim, et al., “Bio-inspired artificial vision and neuromorphic image processing devices,” Adv. Mater. Technol., Vol. 7, 2100144, pages 1-22, (2022).

Reference [8]. Q. Zhang, et al., “Organic field effect transistor-based photonic synapses: materials, devices, and applications,” Adv. Funct. Mater., Vol. 31 (49), 2106151, pages 1-16, 2021.

Reference [9]. S. Song, et al., “Recent Progress of Optoelectronic and All-Optical Neuromorphic Devices: A Comprehensive Review of Device Structures, Materials, and Applications,” Adv. Intell. Syst., Vol. 3(4), 2000119, (2021).

Reference [10]. M. Lee, et al., “Nanomaterial-Based Synaptic Optoelectronic Devices for In-Sensor Preprocessing of Image Data,” ACS Omega 2023, Vol. 8(6), pages 5209-5224.

Reference [11]. U.S. Patent Publication No. 2022/0083850A1, “Optoelectronic Synapse Based on Perovskite Quantum Dot-Carbon Nanotube for Neuromorphic Computing,” March 17, 2022.

Reference [12]. Chinese Patent Publication No. CN106981567B, “A kind of artificial synapse device and its modular approach based on photoelectric coupling memristor,” November 5, 2019.

Reference [13]. J. Meng, J., et al., ‘Ultraviolet Irradiation-Controlled Memory Effect in Graphene Field-Effect Transistors,” Small, Vol. 9, No. 13, pages 2240-2244 July 2013.

Reference [14]. L. Ju, et al., “Photoinduced doping in heterostructures of graphene and boron nitride,” Letters, Nature Nanotechnology, Vol. 9, No. 5, pages 348-352, April 2014.

Reference [15]. P. H. Ho, et al., “Precisely Controlled Ultrastrong Photoinduced Doping at Graphene-Heterostructures Assisted by Trap-State-Mediated Charge Transfer,” Adv. Mater., Vol. 27, No. 47, pages 7809-7815 October 2018.

Reference [16]. A. B. G. Trabelsi, et al., “Morphological imperfections of epitaxial graphene: From a hindrance to the generation of new photo-responses in the visible domain,” Nanoscale, Vol. 9, No. 32, pages 11463-11474, May 2017.

Reference [17]. G. Cao, et al., “Photoinduced hysteresis of graphene field-effect transistors due to hydrogen-complexed defects in silicon dioxide,” ACS Appl. Mater. Interfaces, Vol. 11, No. 12, pages 12170-12178, March 2019.

Reference [18]. C. Frydendahl, et al., “Photo Memtransistor Based on CMOS Flash Memory Technology on Graphene with Neuromorphic Applications,” ACS Photonics, Vol. 8, No. 9, pages 2659-2665 May 2021.

Reference [19]. J. Liu, et al., “Application of organic-graphene hybrids in high performance photodetectors,” Mater. Chem. Front., Vol. 4, No. 2, pages 354-368, November 2019.

Reference [20]. G. Li, “Artificial optical synaptic devices with ultra-low power consumption,” Light: Science & Applications, Vol. 12, No. 24, 3 pages, 2023.

1. A photosynapse device comprising:
an insulating layer;
a semiconductor layer on the insulating layer;
a photoactive layer on the semiconductor layer, wherein the semiconductor layer is between the insulating layer and the photoactive layer; and
a pair of spaced apart electrodes electrically coupled with the semiconductor layer.

2. The photosynapse device of claim 1, wherein the semiconductor layer has an atomic scale thickness.

3. The photosynapse device of claim 1, wherein the semiconductor layer has a thickness less than about 5 nanometers.

4. The photosynapse device of claim 1, wherein the semiconductor layer comprises a 2-dimensional electronic semiconductor layer.

5. The photosynapse device of claim 1, wherein the semiconductor layer comprises at least one of graphene, a chalcogenide, a group IV semiconductor material, a metal oxide, a metal boride, a pnictide material, a perovskite material, a nitride material, silicon, phosphorous, a metalloid, boron, germanium, antimony, and/or bismuth.

6. The photosynapse device of claim 1, wherein the insulating layer comprises a silicon-based insulating layer.

7. The photosynapse device of claim 6, wherein the silicon-based insulating layer comprises at least one of silicon carbide, quartz, silicon dioxide, and/or silicon nitride.

8. The photosynapse device of claim 1, wherein the photoactive layer comprises an organic photoactive layer.

9. The photosynapse device of claim 8, wherein the organic photoactive layer comprises at least one of an organic photoactive dye, and/or an azo-dye.

10. The photosynapse device of claim 8, wherein the organic photoactive layer comprises at least one of Congo red, azo-dye Congo Red, Brilliant yellow, Methyl Orange, perylene, tera-isopropyl-perylene, HAT5, an intrinsic polymer, a modified polymer, a mesoporous system, a microporous system, a metal-organic framework (MOF), a zeolite, a biomaterial, and/or a hydrogel.

11. The photosynapse device of claim 1, wherein each of the electrodes comprises at least one of gold, aluminum, nickel, silver, poly(3,4-ethylenedioxythiophene) polystyrene sulfonate PEDOT:PSS, and/or chromium.

12. The photosynapse device of claim 1 further comprising:
a lens optically coupled with the photoactive layer, wherein the lens is oriented to direct photonic stimulus to the photoactive layer.

13. The photosynapse device of claim 1 further comprising:
a light emitting diode optically coupled with the photoactive layer.

14. The photosynapse device of claim 13, wherein the light emitting diode is configured to generate a photonic stimulus that is directed to the photoactive layer.

15. A photonic integrated circuit (PIC) device comprising:
a substrate; and
an array of photosynapse devices on the substrate, wherein the array of photosynapse devices includes first and second photosynapse devices;
wherein the first photosynapse device includes a first insulating layer on the substrate, a first semiconductor layer on the first insulating layer, a first photoactive layer on the first semiconductor layer, and a first pair of spaced apart electrodes electrically coupled with the first semiconductor layer, with the first semiconductor layer being between the first photoactive layer and the first insulating layer; and
wherein the second photosynapse device includes a second insulating layer on the substrate, a second semiconductor layer on the second insulating layer, a second photoactive layer on the second semiconductor layer, and a second pair of spaced apart electrodes electrically coupled with the second semiconductor layer, with the second semiconductor layer being between the second photoactive layer and the second insulating layer.

16. The photonic integrated circuit device of claim 15 further comprising:
a conductive row line extending in a first direction, wherein the conductive row line is electrically coupled with a first electrode of the first pair and with a first electrode of the second pair;
a first conductive column line extending in a second direction different than the first direction, wherein the first conductive column line is electrically coupled with a second electrode of the first pair; and
a second conductive column line extending in the second direction and spaced apart from the first conductive column line, wherein the second conductive column line is electrically coupled with a second electrode of the second pair.

17. The photonic integrated circuit device of claim 15 further comprising:
a lens optically coupled with the array of photosynapse devices, wherein the lens is oriented to direct photonic stimulus to the first photoactive layer of the first photosynapse device and to the second photoactive layer of the second photosynapse device.

18. The photonic integrated circuit device of claim 15 further comprising:
an array of light emitting diodes on the array of photosynapse devices, wherein the array of light emitting diodes includes a first light emitting diode optically coupled with the first photosynapse device and a second light emitting diode optically coupled with the second photosynapse device.

19. The photonic integrated circuit device of claim 18, wherein the first light emitting diode is configured to generate a first photonic stimulus that is directed to the first photoactive layer of the first photosynapse device, and wherein the second light emitting diode is configured to generate a second photonic stimulus that is directed to the second photoactive layer of the second photosynapse device.

20. The photonic integrated circuit device of claim 15, wherein the first and second insulating layers comprise respective first and second spaced apart islands of an insulating material, wherein the first and second semiconductor layers comprise respective first and second spaced apart islands of a semiconductor material, and wherein the first and second photoactive layers comprise respective first and second spaced apart islands of a photoactive material.

21. The photonic integrated circuit device of claim 15, wherein the first and second insulating layers comprise respective first and second portions of a continuous layer of an insulating material, and wherein the first and second semiconductor layers comprise respective first and second spaced apart islands of a semiconductor material.

22. The photonic integrated circuit device of claim 15, wherein the first and second semiconductor layers comprise respective first and second spaced apart islands of a semiconductor material, and wherein the first and second photoactive layers comprise respective first and second portions of a continuous layer of a photoactive material.

23. (canceled)

24. (canceled)

25. (canceled)

26. (canceled)

27. (canceled)

28. (canceled)

29. (canceled)

30. (canceled)

31. (canceled)

32. (canceled)
